(19) United States
(12) Patent Application Publication
(10) Pub. No.: US 2026/0246454 A1
(43) Pub. Date: Aug. 20, 2026

(54) GENERALIZED CDC-ERROR-FREE CONTROL AND STATUS REGISTER (CSR) STRUCTURE THAT CAN OPERATE IN TWO CLOCK DOMAINS, SUPPORTING CLOCK STOPS, OPERATIONS WITHOUT FLOW-CONTROL, AND BIDIRECTIONAL COMMUNICATION

(71) Applicant: STMicroelectronics International N.V., Geneva (CH)

(72) Inventor: Liuhao WU, Singapore (SG)

(73) Assignee: STMicroelectronics International N.V., Geneva (CH)

(21) Appl. No.: 19/057,072

(22) Filed: Feb. 19, 2025

(51) Int. Cl. H03K 3/037; H03K 19/21

(52) U.S. Cl. CPC H03K 3/037; H03K 19/21

(57) ABSTRACT

A synchronization circuit provides bidirectional communication between two clock domains without requiring feedback signals. The circuit includes first and second clock domain circuits, each having a flip-flop with enable control logic and an XOR gate for output generation. In each domain, the output of the flip-flop is inverted and fed back to its input, creating a toggle mechanism controlled by set and clear signals. The XOR gate in each domain compares its local flip-flop state with a synchronized version of the other domain's flip-flop state to generate register output clock signals. Synchronizers or qualified connections between domains ensure reliable cross-domain communication. The circuit maintains operation when either clock stops, preserving state changes for synchronization when clocks resume.

### TECHNICAL FIELD

This disclosure relates to synchronization circuits for cross-domain communication in integrated circuits having multiple clock domains.

### BACKGROUND

Control and Status Registers (CSR) enable information exchange between central processor units (CPUs) and intellectual property (IP) circuit blocks, which are digital macro components. These exchanges often occur between two clock domains and are to work in both directions. Managing clock domain crossing synchronizations becomes challenging, particularly when one or both clocks may stop due to standby modes or other IP clock behaviors.

Existing solutions typically use two specialized types of synchronization cells. Status synchronization cell modules are designed for signals that represent a condition or status lasting more than one clock cycle. Common examples include “busy” or “ready” signals, which remain active until the condition changes. These modules implement a series of flip-flops in the destination clock domain, with each stage helping to resolve potential metastability issues that can occur when sampling signals across clock domains. The first flip-flop captures the incoming signal, while subsequent stages further stabilize it before it is used by the destination logic, providing for reliable transfer of status information.

Event synchronization cell modules handle signals that are only active for one clock cycle. Examples include “data valid” flags or “trigger” signals, which briefly rise and fall. These modules employ a more complex structure to provide for reliable transfer. They may include a level-sensitive latch or flip-flop in the source domain to capture and hold the pulse, multiple synchronization stages in the destination domain, and handshaking logic to ensure each event is properly acknowledged and cleared.

For other multi-clock domain registers, custom synchronization structures tailored to each specific need are often needed. This may lead to complex, repetitive designs that may be prone to errors.

A generalized register design that works across clock domains and handles stopped clocks would help address these problems. Such a generalized register design could improve efficiency and provide for consistent implementation across applications. As such, further development is needed.

### SUMMARY

A synchronization circuit has a first clock domain circuit and a second clock domain circuit. The first clock domain circuit includes a first flip-flop with a data input, enable input, and data output, clocked by a first clock signal. The first clock domain circuit has a first AND gate with a first input for a first control signal and a second input, and a second AND gate with a first input for a second control signal and a second input. A first OR gate has inputs coupled to outputs of the first and second AND gates and an output coupled to the enable input of the first flip-flop. A first inverter has an input coupled to the data output of the first flip-flop and an output coupled to the data input of the first flip-flop. A first synchronizer has an input coupled to receive an output signal from the second clock domain circuit and is clocked by the first clock signal. A first XOR gate has a first input coupled to the data output of the first flip-flop and a second input coupled to an output of the first synchronizer to provide a first register output clock signal. The second input of the first AND gate receives the first register output clock signal and the second input of the second AND gate receives an inverted version of the first register output clock signal.

The second clock domain circuit includes a second flip-flop with a data input, enable input, and data output, clocked by a second clock signal. The second clock domain circuit has a third AND gate with a first input for a third control signal and a second input, and a fourth AND gate with a first input for a fourth control signal and a second input. A second OR gate has inputs coupled to outputs of the third and fourth AND gates and an output coupled to the enable input of the second flip-flop. A second inverter has an input coupled to the data output of the second flip-flop and an output coupled to the data input of the second flip-flop. A second XOR gate has a first input coupled to the data output of the second flip-flop and a second input coupled to receive a synchronized version of the first flip-flop output to provide a second register output clock signal. The second input of the third AND gate receives the second register output clock signal and the second input of the fourth AND gate receives an inverted version of the second register output clock signal.

The circuit may include a second synchronizer with an input coupled to the data output of the first flip-flop and clocked by the second clock signal, where an output of the second synchronizer provides the synchronized version of the first flip-flop output to the second input of the second XOR gate.

The synchronized version of the first flip-flop output may include a direct connection from the data output of the first flip-flop to the second input of the second XOR gate.

The circuit may include a qualifier flip-flop with a data input coupled to receive the data output of the first flip-flop and an enable input coupled to receive a qualifier signal, where a data output of the qualifier flip-flop provides the synchronized version of the first flip-flop output to the second input of the second XOR gate.

The first control signal may be a first clear signal, the second control signal may be a first set signal, the third control signal may be a second clear signal, and the fourth control signal may be a second set signal.

The first control signal may be a first register input signal, the second control signal may be the first register input signal, the third control signal may be a second register input signal, and the fourth control signal may be the second register input signal.

The first clock domain circuit may maintain operation when the second clock signal is stopped and the second clock domain circuit may maintain operation when the first clock signal is stopped.

State changes in the second clock domain circuit during stoppage of the first clock signal may be preserved and synchronized to the first clock domain circuit when the first clock signal resumes.

The synchronization circuit enables signals to be synchronized between clock domains by receiving first and second control signals in a first clock domain operating on a first clock signal, toggling a state of a first flip-flop in the first clock domain based on the first and second control signals, and generating a first register output clock signal by comparing the state of the first flip-flop with a synchronized signal from a second clock domain. The circuit receives third and fourth control signals in the second clock domain operating on a second clock signal, toggles a state of a second flip-flop in the second clock domain based on the third and fourth control signals, and generates a second register output clock signal by comparing the state of the second flip-flop with a synchronized version of the first flip-flop state.

### BRIEF DESCRIPTION OF THE DRAWINGS

FIG. 1 is a block diagram of a synchronization circuit for clock domain crossing with bidirectional control.

FIG. 2 is a timing diagram showing control signal operation between two clock domains in the synchronization circuit of FIG. 1.

FIG. 3 is a timing diagram showing operation of the synchronization circuit during CPU standby conditions.

FIG. 4 is a block diagram of a first variation of the synchronization circuit with direct cross-domain connection.

FIG. 5 is a timing diagram showing operation of the synchronization circuit variation of FIG. 4.

FIG. 6 is a block diagram of a second variation of the synchronization circuit using a qualifier flip-flop.

FIG. 7 is a block diagram of a third variation of the synchronization circuit using register input signals.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

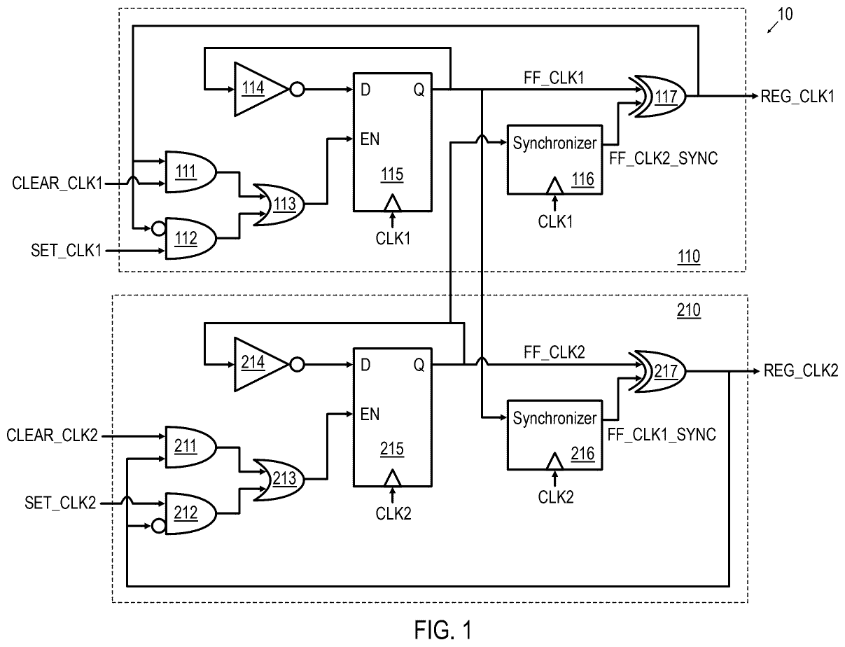

As shown in FIG. 1, in a first clock domain 110, the control and status register (CSR) 10 includes an AND gate 111 receiving as input the first register output clock signal REG_CLK1 as well as a first clear clock signal CLEAR_CLK1, and an AND gate 112 receiving an inverted version of the first register output clock signal REG_CLK1 as well as a first set clock signal SET_CLK1. An OR gate 113 receives as input the outputs of AND gates 111 and 112, and provides output to an enable input EN of flip flop 115. A data input D of flip flop 115 receives an inverted version of the data output Q of flip flop 115 from inverter 114, with this flip flop 115 being clocked by a first clock signal CLK1, and with the data output Q of this flip flop 115 also being provided to a first input of XOR gate 117 and to the synchronizer 216 in a second clock domain 210). A second input of the XOR gate 117 receives the output of synchronizer 116. Synchronizer 116 is clocked by the first clock signal CLK1 and receives the output of flip flop 215 (located in the second clock domain 210) as its input.

In the second clock domain 210, the CSR 10 includes an AND gate 211 receiving as input the second register output clock signal REG_CLK2 as well as a second clear clock signal CLEAR_CLK2, and an AND gate 212 receiving an inverted version of the second register output clock signal REG_CLK2 as well as a second set clock signal SET_CLK2. An OR gate 213 receives as input the outputs of AND gates 211 and 212, and provides output to an enable input EN of flip flop 215. A data input D of flip flop 215 receives an inverted version of the data output Q of flip flop 215 from inverter 214, with this flip flop 215 being clocked by a second clock signal CLK2, and with the data output Q of this flip flop 215 also being provided to a first input of XOR gate 217 (and to the synchronizer 116 in the first clock domain 110). A second input of the XOR gate 217 receives the output of synchronizer 216. Synchronizer 216 is clocked by the second clock signal CLK2 and receives the output of flip flop 115 (located in the first clock domain 110) as its input.

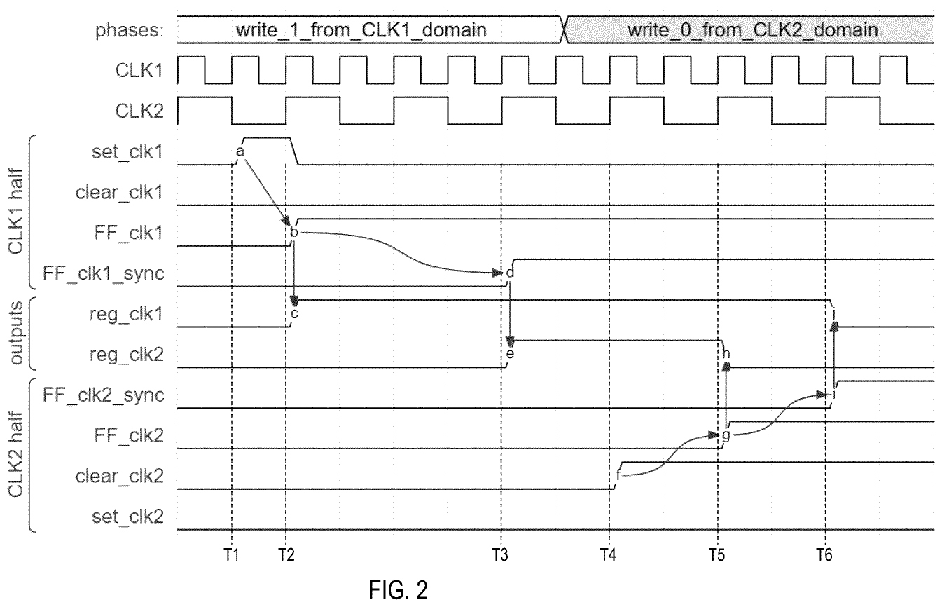

Operation of the CSR 10 is now described. As shown in the timing diagram of FIG. 2, operation proceeds in two phases, namely writing a logic 1 from the CLK1 domain and writing a logic 0 from the CLK2 domain. During the write 1 phase, when SET_CLK1 is asserted at time T1 (point a), it triggers flip-flop 115 through AND gate 112 and OR gate 113 to toggle its state (assert FF_CLK1) at time T2 (point b), causing an immediate change in REG_CLK1 through XOR gate 117 (point c). This change propagates through synchronizer 216 in the CLK2 domain, shown as FF_CLK1_SYNC in the diagram at time T3, leading to a delayed rise in REG_CLK2 via XOR gate 217 (points d to e).

Note that FF_CLK1_SYNC is the synchronized output of flip-flop 115 as seen in the CLK2 domain via synchronizer 216, while FF_CLK2_SYNC is the synchronized output of flip-flop 215 as seen in the CLK1 domain via synchronizer 116.

During the write 0 phase, the reverse operation occurs when CLEAR_CLK2 asserts at time T4 (point f) from the CLK2 domain. The signal passes through AND gate 211 and OR gate 213 to toggle flip-flop 215 (assert FF_CLK2) at time T5 (point g), immediately affecting REG_CLK2 through XOR gate 217 (point h). REG_CLK1 then updates at time T6 after the synchronization delay through synchronizer 116 and XOR gate 117 (points i to j), as shown by the FF_CLK2_SYNC waveform.

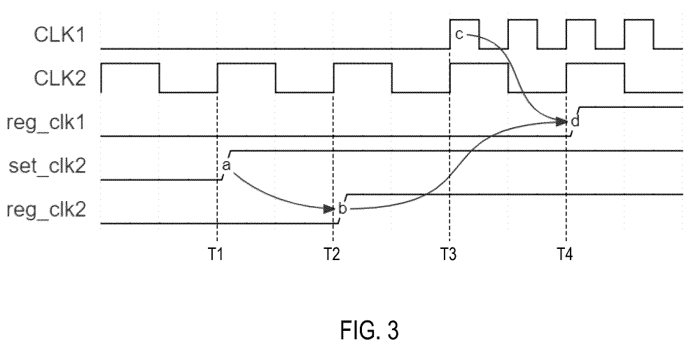

The design maintains robust operation even during CPU standby conditions. As illustrated in timing diagram of FIG. 3, when CLK1 stops, the CLK2 domain remains operational. During this period, flip-flop 215 continues to respond to CLK2 domain actions, with REG_CLK2 updating appropriately between times T1 and T2 (points a to b). Rather than losing state information during the inactive period of CLK1, the circuit preserves the CLK2 domain changes. When CLK1 resumes operation at time T3 (point c), synchronizer 116 safely transfers the accumulated state changes from flip-flop 215 to the CLK1 domain, causing REG_CLK1 to update accordingly at time T4 (point d) after several CLK1 cycles.

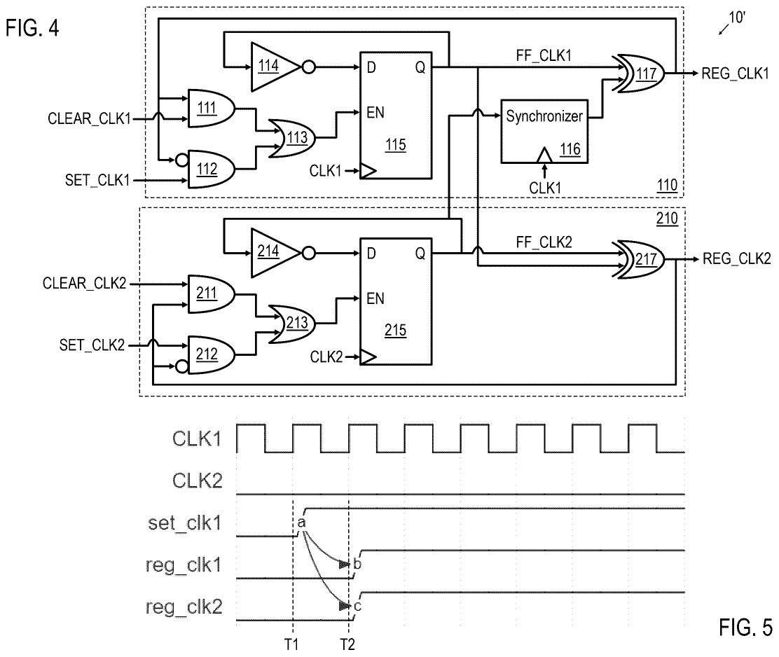

A variation of the design, shown in FIG. 4, removes synchronizer 216 from the CLK2 domain. In this configuration, XOR gate 217 receives its inputs directly from the Q outputs of flip-flops 115 and 215. As illustrated in the timing diagram of FIG. 5, when SET_CLK1 is asserted at time T1 (point a), the operation in the CLK1 domain remains the same, namely flip-flop 115 toggles and REG_CLK1 updates at time T2 (point b). However, without the synchronizer delay, REG_CLK2 now updates immediately at point c. This modification is suitable for systems where CLK2 is stopped while CLK1 remains active, as shown in the timing diagram where CLK2 remains low. The single synchronizer 116 in the CLK1 domain maintains safety for transfers from CLK2 to CLK1 when CLK2 is active.

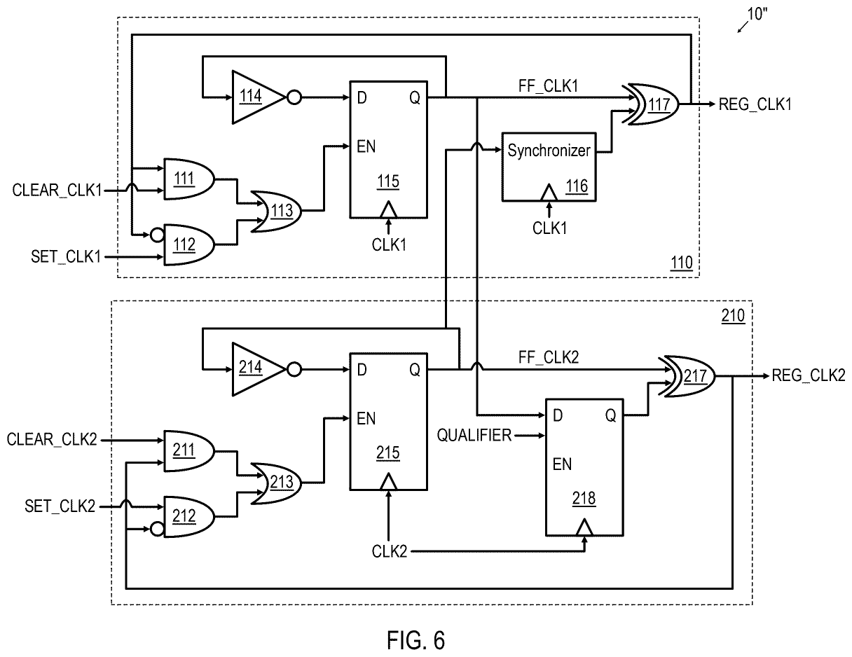

A second variation, illustrated in FIG. 6, replaces synchronizer 216 in the second clock domain 210 with flip-flop 218. This flip-flop 218 receives the output from flip-flop 115 at its data input and a QUALIFIER signal at its enable input, providing qualified control over when the CLK1 domain changes affect the CLK2 domain through XOR gate 217. This configuration is particularly useful for convergence scenarios where multiple CSR values are used simultaneously in the CLK2 domain. Instead of implementing separate synchronizers for each CSR, a single QUALIFIER signal can control multiple CSRs, thus avoiding potential convergence errors that could arise from synchronizing CLK1 signals at multiple points.

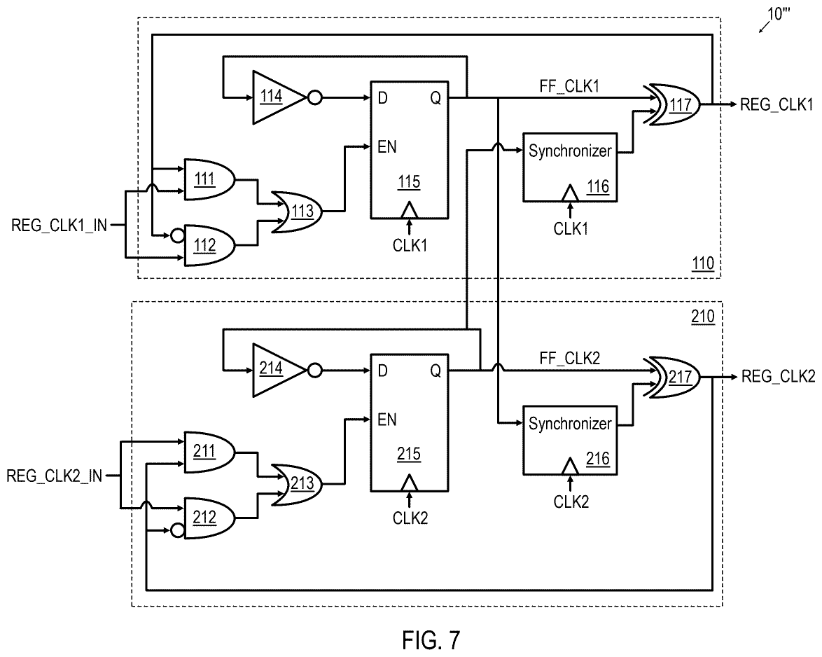

FIG. 7 shows a third variation where the control inputs are modified. Instead of separate SET and CLEAR signals, the design uses register input signals REG_CLK1_IN and REG_CLK2_IN. These signals feed directly into AND gates 111, 112 and 211, 212 respectively. Thanks to the design's support for state inputs, this variation can be easily adapted to provide straightforward register IN and register OUT functionality by adding a single inverter at the clear input. This creates a simplified interface while maintaining the core functionality of the circuit.

Thus, it can be appreciated that the output of each clock domain is generated by the logical XORing of the local flip-flop output (flip-flop 115 for the CLK1 domain, flip-flop 215 for the CLK2 domain) with the synchronized version of the flip-flop output of the other clock domain. When the CLK1 frequency significantly exceeds CLK2, rapid successive operations in the CLK1 domain may not all be captured in CLK2 domain. This frequency limitation serves to protect against metastability issues that could arise from too-frequent cross-domain transitions. The CSR design functions with both pulse and state input signals, where repetitive set operations will not cause unwanted output toggles due to the enable pin logic comparing actions with the register output. This is particularly useful for applications where the same value might be written multiple times or held constant (state input), as this design provides for consistent behavior regardless of input pattern or timing, maintaining data integrity across the clock domains.

The synchronization cell design described above offers advantages for multi-clock domain IP implementations. For example, in a serial peripheral interface (SPI) communication IP running on a dedicated 26 MHz clock that interfaces with a 200 MHz CPU domain via advanced peripheral bus (APB), this design enables the SPI to maintain data transmission and reception with external devices even when the CPU enters standby mode. The CSRs can operate independently without the CPU clock while avoiding errors when the CPU clock resumes.

The use of XOR gates comparing values stored in two flip-flops enables bidirectional communication without requiring feedback signals. By storing state toggles rather than direct values, the design eliminates the need for acknowledgment that the flip-flop in the other clock domain has been updated. The symmetrical structure provides full controllability from both clock domains.

Moreover, this design achieves the additional advantages of supporting true bidirectional communication across two clock domains, enabling independent operation during clock stops (standby/wakeup scenarios), eliminating the need for flow control mechanisms (wait/ready/feedback signals), and providing a uniform, general-purpose solution that can be readily reused.

This synchronization cell can be utilized broadly across multi-clock domain IPs, including communication interfaces, peripheral controllers, and cryptographic modules. The simple interface and reusable architecture make it particularly useful for standardizing clock domain crossing solutions across complex system-on-chip designs.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A synchronization circuit, comprising:
a first clock domain circuit including;
a first flip-flop having a data input, an enable input, and a data output, the first flip-flop being clocked by a first clock signal;
a first AND gate having a first input configured to receive a first control signal and a second input;
a second AND gate having a first input configured to receive a second control signal and a second input;
a first OR gate having inputs coupled to outputs of the first and second AND gates and an output coupled to the enable input of the first flip-flop;
a first inverter having an input coupled to the data output of the first flip-flop and an output coupled to the data input of the first flip-flop;
a first synchronizer having an input coupled to receive an output signal from a second clock domain circuit and clocked by the first clock signal; and
a first XOR gate having a first input coupled to the data output of the first flip-flop and a second input coupled to an output of the first synchronizer to provide a first register output clock signal;
wherein the second input of the first AND gate is coupled to receive the first register output clock signal and the second input of the second AND gate is coupled to receive an inverted version of the first register output clock signal; and
a second clock domain circuit including:
a second flip-flop having a data input, an enable input, and a data output, the second flip-flop being clocked by a second clock signal;
a third AND gate having a first input configured to receive a third control signal and a second input;
a fourth AND gate having a first input configured to receive a fourth control signal and a second input;
a second OR gate having inputs coupled to outputs of the third and fourth AND gates and an output coupled to the enable input of the second flip-flop;
a second inverter having an input coupled to the data output of the second flip-flop and an output coupled to the data input of the second flip-flop; and
a second XOR gate having a first input coupled to the data output of the second flip-flop and a second input coupled to receive a synchronized version of the first flip-flop output to provide a second register output clock signal;
wherein the second input of the third AND gate is coupled to receive the second register output clock signal and the second input of the fourth AND gate is coupled to receive an inverted version of the second register output clock signal.

2. The synchronization circuit of claim 1, further comprising a second synchronizer having an input coupled to the data output of the first flip-flop and clocked by the second clock signal, wherein an output of the second synchronizer provides the synchronized version of the first flip-flop output to the second input of the second XOR gate.

3. The synchronization circuit of claim 1, wherein the synchronized version of the first flip-flop output comprises a direct connection from the data output of the first flip-flop to the second input of the second XOR gate.

4. The synchronization circuit of claim 1, further comprising: a qualifier flip-flop having a data input coupled to receive the data output of the first flip-flop and an enable input coupled to receive a qualifier signal, wherein a data output of the qualifier flip-flop provides the synchronized version of the first flip-flop output to the second input of the second XOR gate.

5. The synchronization circuit of claim 1, wherein the first control signal comprises a first clear signal, the second control signal comprises a first set signal, the third control signal comprises a second clear signal, and the fourth control signal comprises a second set signal.

6. The synchronization circuit of claim 1, wherein the first control signal comprises a first register input signal, the second control signal comprises the first register input signal, the third control signal comprises a second register input signal, and the fourth control signal comprises the second register input signal.

7. The synchronization circuit of claim 1, wherein the first clock domain circuit is configured to maintain operation when the second clock signal is stopped and the second clock domain circuit is configured to maintain operation when the first clock signal is stopped.

8. The synchronization circuit of claim 6, wherein state changes in the second clock domain circuit during stoppage of the first clock signal are preserved and synchronized to the first clock domain circuit when the first clock signal resumes.

9. A method of synchronizing signals between clock domains, comprising:
receiving first and second control signals in a first clock domain operating on a first clock signal;
toggling a state of a first flip-flop in the first clock domain based on the first and second control signals;
generating a first register output clock signal by comparing the state of the first flip-flop with a synchronized signal from a second clock domain;
receiving third and fourth control signals in the second clock domain operating on a second clock signal;
toggling a state of a second flip-flop in the second clock domain based on the third and fourth control signals; and
generating a second register output clock signal by comparing the state of the second flip-flop with a synchronized version of the first flip-flop state.

10. The method of claim 9, wherein synchronizing between clock domains comprises:
synchronizing the second flip-flop state to the first clock domain using a first synchronizer to generate the synchronized signal; and
synchronizing the first flip-flop state to the second clock domain using a second synchronizer to generate the synchronized version of the first flip-flop state.

11. The method of claim 9, wherein the first and second control signals comprise clear and set signals for the first clock domain, and the third and fourth control signals comprise clear and set signals for the second clock domain.

12. The method of claim 9, wherein the first and second control signals comprise a first register input signal, and the third and fourth control signals comprise a second register input signal.

13. The method of claim 9, further comprising:
maintaining operation of the first clock domain when the second clock signal is stopped;
maintaining operation of the second clock domain when the first clock signal is stopped; and
preserving state changes that occur in one clock domain during stoppage of the other clock domain.

14. The method of claim 13, further comprising synchronizing the preserved state changes to the stopped clock domain when its clock signal resumes.

15. A synchronization device, comprising:
a first domain circuit configured to operate on a first clock signal and including a first state storage element;
a second domain circuit configured to operate on a second clock signal and including a second state storage element;
wherein the first domain circuit is configured to:
receive first control signals;
toggle a state of the first state storage element responsive to the first control signals; and
generate a first register output clock signal by comparing the state of the first state storage element with a synchronized signal from the second domain circuit; and
wherein the second domain circuit is configured to:
receive second control signals;
toggle a state of the second state storage element responsive to the second control signals; and
generate a second register output clock signal by comparing the state of the second state storage element with a synchronized version of the first state storage element state.

16. The synchronization device of claim 15, wherein:
the first domain circuit comprises a first synchronizer configured to synchronize the second state storage element state to the first clock signal to generate the synchronized signal; and
the second domain circuit comprises a second synchronizer configured to synchronize the first state storage element state to the second clock signal to generate the synchronized version of the first state storage element state.

17. The synchronization device of claim 15, wherein:
the first domain circuit is configured to maintain operation when the second clock signal is stopped; and
the second domain circuit is configured to maintain operation when the first clock signal is stopped.

18. The synchronization device of claim 17, wherein:
the second domain circuit is configured to preserve state changes that occur during stoppage of the first clock signal; and
the first domain circuit is configured to receive and synchronize the preserved state changes when the first clock signal resumes operation.

19. The synchronization device of claim 15, wherein:
the first state storage element comprises a first flip-flop having an enable input controlled by the first control signals; and
the second state storage element comprises a second flip-flop having an enable input controlled by the second control signals.

20. The synchronization device of claim 15, wherein:
the first domain circuit comprises a first XOR gate configured to perform the comparing of the first state storage element state with the synchronized signal; and
the second domain circuit comprises a second XOR gate configured to perform the comparing of the second state storage element state with the synchronized version of the first state storage element state.
